(19) United States
(12) Patent Application Publication
(10) Pub. No.: US 2013/0040516 A1
(43) Pub. Date: Feb. 14, 2013

(54) TRANSPARENT ELECTRODE BASED ON COMBINATION OF TRANSPARENT CONDUCTIVE OXIDES, METALS AND OXIDES

(71) Applicants: Valerio Pruneri, Castelldefels (ES); Dhriti Sundar Ghosh, Castelldefels (ES); Tong Lai Chen, Castelldefels (ES)

(72) Inventors: Valerio Pruneri, Castelldefels (ES); Dhriti Sundar Ghosh, Castelldefels (ES); Tong Lai Chen, Castelldefels (ES)

(21) Appl. No.: 13/578,902

(22) PCT Filed: Feb. 15, 2011
(86) PCT No.: PCT/EP11/52199

§ 371 Date: Oct. 18, 2012

(30) Foreign Application Priority Data
Feb. 19, 2010 (ES) P201030240

(51) Int. Cl. H01L 31/0224; C23C 14/34; D03D 9/00; B82Y 30/00

(52) U.S. Cl. 442/1; 428/332; 204/192.29; 977/762; 977/742

(57) ABSTRACT

The invention disclosure relates to an electrode comprising a transparent conductive oxide (TCO) and an ultra thin metal film (UTMF) deposited on the TCO. In addition the UTMF is oxidized or covered by an oxide layer. In this way the underlying TCO is protected/compatible to other materials and the loss of transparency is reduced.

### FIELD OF THE INVENTION

The present invention relates to optically transparent and electrically conductive electrodes for, for example, optoelectronic applications.

### STATE OF THE ART

Transparent electrodes (TEs), i.e. films which can conduct electricity and at the same time transmit light, are of crucial importance for many optical devices, such as photovoltaic cells, organic light emitting diodes, integrated electro-optic modulators, laser displays, photo-detectors, etc. From an application point of view, besides large optical transparency in the wavelength range of interest and adequate electrical conductivity, transparent electrodes should possess other key features, such as easy processing (e.g. possibility for large scale deposition), compatibility with other materials that form the same device (e.g. active layers), stability against temperature, mechanical and chemical stress, and low cost.

TEs have been the subject of intensive research because of their critical importance in a wide range of applications, including LEDs, photovoltaic cells, detectors and displays [C. G. Granqvist, “Transparent conductors as solar energy materials: A panoramic review”, Solar Energy Materials and Solar Cells 91, 1529 (2007); T. Minami, “Transparent conducting oxide semiconductors for transparent electrodes”, Semicond. Sci. Technol. 20 No 4 (2005) S35-S44]. So far transparent conductive oxides (TCOs), including conventional indium tin oxide (ITO) and aluminum doped zinc oxide (AZO) have mainly been used in the optoelectronics industry [A. Kuroyanagi, “Crystallographic characteristics and electrical properties of Al doped ZnO thin films prepared by ionized deposition”, J. Appl. Phys. 66, 5492 (1989); Y. Igasaki et.al, “The effects of deposition rates on the structural and electrical properties of ZnO:Al films deposited on (1120) oriented sapphire substrates”, J. Appl. Phys. 70, 3613 (1991)]. Although state-of-the-art TCOs have excellent optical transmission and low sheet resistance, they suffer from several drawbacks, including indium shortage for ITO, chemically vulnerability for AZO. In particular, low stability under temperature, reduced or rich oxygen atmosphere, humidity or salinity can be significant drawbacks. For example it has been pointed out that, when TCO films are subjected to temperature, humidity, oxygen, water or their combination, this might be responsible for the degradation of their electrical performance (increase in sheet resistance) [T. Miyata et al., “Stability of nano-thick transparent conducting oxide films for use in a moist environment”, Thin Solid Films 516, 1354-1358 (2008)]. In some cases TCO is not compatible with other material forming the device and in contact with it, e.g. migration of indium/oxygen from In₂O₃ into organic and active layers. In other cases, additional layers might be needed to improve the functionality of TCOs, e.g. the work function for specific applications.

Recently there has been some interest in combining the TCO technology with metals to improve their properties, in which a very thin metal layer (0.5-1.5 nm), preferably 0.5 nm, is deposited on the top of TCO to improve their functionality [J. C. Bernede, “Organic optoelectronic component electrode, comprising at least one layer of a transparent oxide coated with a metallic layer, and corresponding organic optoelectronic component”, WO2009016092]. It is found that such an ultra thin metal film (UTMF) improves the device performance due to the better matching of energy levels between the transparent electrode and organic layer which in turn implies lower injection barrier. Such a thin film of metal will however presents several drawbacks. It typically induces a loss in the transparency of the electrode. In addition it does not cover the whole surface and thus will form discrete islands structure, as it is shown in related publications [see for example J. C. Bernede, “Improvement of organic solar cell performances using a zinc oxide anode coated by an ultrathin metallic layer”, Applied Phys. Lett. 92, 083304 (2008)]. The island-like metal structure which exposes some underlying TCO layer provides neither stability nor complete protection and compatibility with the environment or other layers forming the devices. The island-like structure can also give rise to light scattering.

### SUMMARY OF THE INVENTION

The present invention aims to provide the electrodes with more transparency, stability, protection and compatibility with the environment. For this purpose, the invention proposes to deposit an UTMF on the TCO. In addition the UTMF is oxidized or covered by an oxide layer. In this way the underlying TCO is protected/compatible to other materials and the loss of transparency is reduced because of the antireflection effect associated to the oxide layer.

The oxide layer can be in contact with the substrate or, in an upside-down embodiment, the transparent conductive oxide can be contact with the substrate. Preferably, the transparent conductive film is selected from indium tin oxide, Al or Ga doped zinc oxide, Ta or Nb doped titanium oxide, F doped tin oxide, and their mixtures. The the ultra thin metal film is preferably selected from Cu, Ni, Cr, Ti, Pt, Ag, Au, Al and their mixtures. The oxide layer can be formed by directly oxidizing the ultra thin metal layer or by depositing an oxide, of for example, Sn or Si. An ultra thin metal layer in the sense of the invention has a thickness below 10 nm. The electrode of the invention can further comprise a conductive mesh with openings on the transparent conductive oxide or the oxide layer, the mesh comprising Ni, Cr, Ti, Al, Cu, Ag, Au, doped ZnO, doped SnO₂, doped TiO₂, carbon nanotubes or Ag nanowires or a mixture thereof. The invention also contemplates methods of manufacturing such transparent electrodes.

### BRIEF DESCRIPTION OF THE DRAWINGS

To complete the description and in order to provide for a better understanding of the invention, a set of drawings is provided. Said drawings form an integral part of the description and illustrate a preferred embodiment of the invention, which should not be interpreted as restricting the scope of the invention, but just as an example of how the invention can be embodied. The drawings comprise the following figures:

FIG. 1 shows the structure, in its simplest form, of the transparent electrode (TE) proposed by this invention.

FIG. 2 is a graph of the optical transparency of TE with AZO220 nm+Ni2 nm (TCO+UTMF) structure before and after oxidation using oxygen plasma.

FIG. 3 shows the sheet resistance and optical transparency as a function of treatment temperature of AZO220 nm (TCO) and AZO220 nm+Ti5 nm treated in oxygen plasma (AZO+UTMF+oxide).

FIG. 4 is a graph of the sheet resistance and optical transparency of AZO220 nm (TCO) and AZO220 nm+Ti5 nm (TCO+UTMF) as a function of treatment temperature.

FIG. 5 shows a comparison of optical transparency of AZO220 nm (TCO) and AZO220 nm+Ti5 nm either oxygen plasma or thermally treated (TCO+UTMF+oxide) in ambient atmosphere.

### DESCRIPTION OF A PREFERRED EMBODIMENT OF THE INVENTION

The electrode of the invention comprises a TCO covered by an UTMF and an oxide layer covering the UTMF. An UTMF in the sense of the invention is a metal film of thickness below 10 nm. The oxide might improve device efficiency since it favors injection and collection of charges into and from the active region of the devices. In summary, through the oxide layer, one can obtain at least one of the following beneficial effects:
Recovery of the transparency which is initially reduced by the application of the UTMF
Protection and stability of the underlying UTMF and TCO
Improvement of the injection barrier for charges by an appropriate choice of metal and its oxide. For example nickel oxide has a higher work function compared to state-of-the-art ITO.

The TCO film is selected from indium tin oxide (ITO), Al or Ga doped zinc oxide (GZO and AZO), Ta or Nb doped titanium oxide (TTO, NTO), F doped tin oxide (FTO), and their mixture. The UTMF is selected from Cu, Ni, Cr, Ti, Pt, Ag, Au, Al and their mixtures. The oxide can be an oxide of the UTMF metals listed above or their mixture or of other elements, such as Si or Sn.

The oxide can be deposited starting from a target of oxide. However in our preferred embodiment it is obtained through direct oxidation of the UTMF either using an oxygen plasma or thermal annealing in ambient atmosphere or both. In this case it is important that the UTMF is not oxidized through its entire thickness. FIG. 2 shows the recovery of the transparency of the TCO (AZO)+UTMF (Ni 2 nm) after oxidation by oxygen plasma. The transparency is calculated by subtracting the transmission of the substrate from the overall transmission of the TE on the substrate.

The substrate of the electrode of the invention can be of any suitable dielectric material on which the TE structure of this invention is grown upon, such as glass, a semiconductor, an inorganic crystal, a rigid or flexible plastic material. Illustrative examples are silica (SiO₂), borosilicate (BK7), silicon (Si), lithium niobate (LiNbO₃), polyethylen naphthalate (PEN), polyethelene terephthalate (PET), among others. Said substrate can be part of an optoelectronic device structure, e.g. an active semiconductor or organic layer.

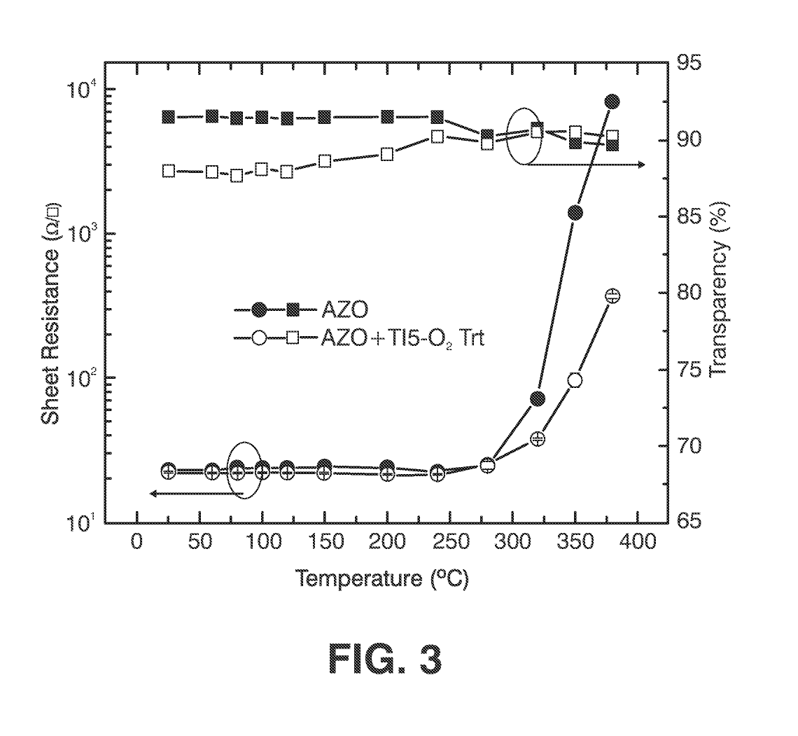

After the oxidation the TE structure becomes more stable. FIG. 3 shows the transparency and sheet resistance of AZO and an AZO+Ti5 nm oxidized layer when subjected to subsequent thermal annealing treatments, each 45 minutes long, at increasing temperatures. The transparency is an average value over the 375-700 nm range. It is clear that the combined TE structure is more stable than the TOC-only TE which experiences a more dramatic increase of sheet resistance and, in particular, starting from lower temperatures. Note that the transparency of the combined structure increases with thermal treatment while the sheet resistance remains practically unchanged, thus indicating that at the beginning the oxidation was far from optimum and could have been taken further so that the level of transparency would have been higher.

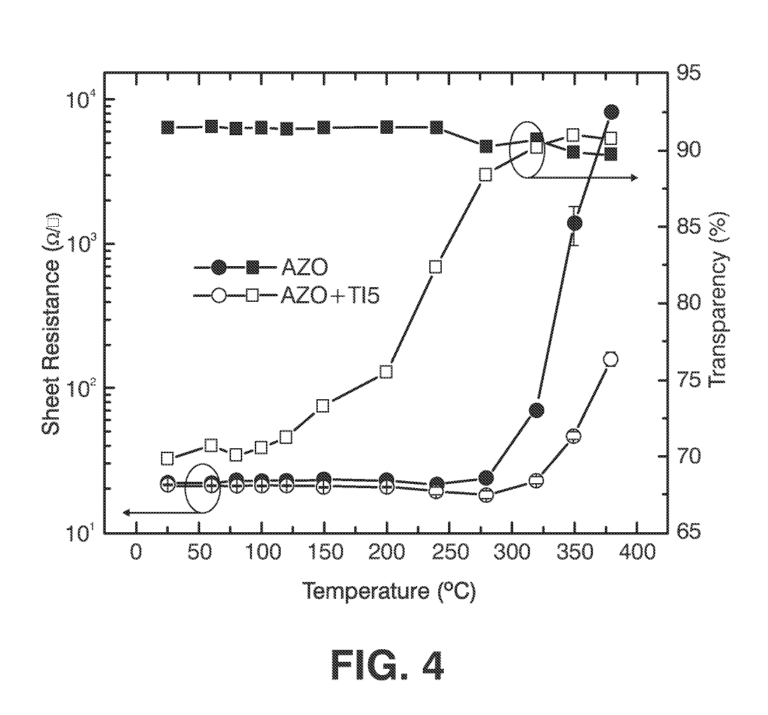

Another way to achieve the combined TE structure is to start from a TCO+UTMF and subject it to thermal annealing in the presence of an oxygen atmosphere. The evolution of transparency and sheet resistance of a combined AZO+Ti5 nm structure subjected to subsequent thermal treatments, each 45 minutes long, in ambient atmosphere is shown in FIG. 4 and again compared to AZO-layer-only structure.

The transparency of the combined structure increases for the thermal treatments at temperature in the range or higher than 100° C. while the corresponding sheet resistance remains constant. In fact the transparency reaches values comparable to TCO-only structure at temperatures in the 250-300° C. range, thus indicating that the formation of the oxide accelerated by the temperature effect improves the quality of the electrode. From the figure it is also clear that the TCO covered by the oxidized UTMF presents a thermal stability higher than the TCO.

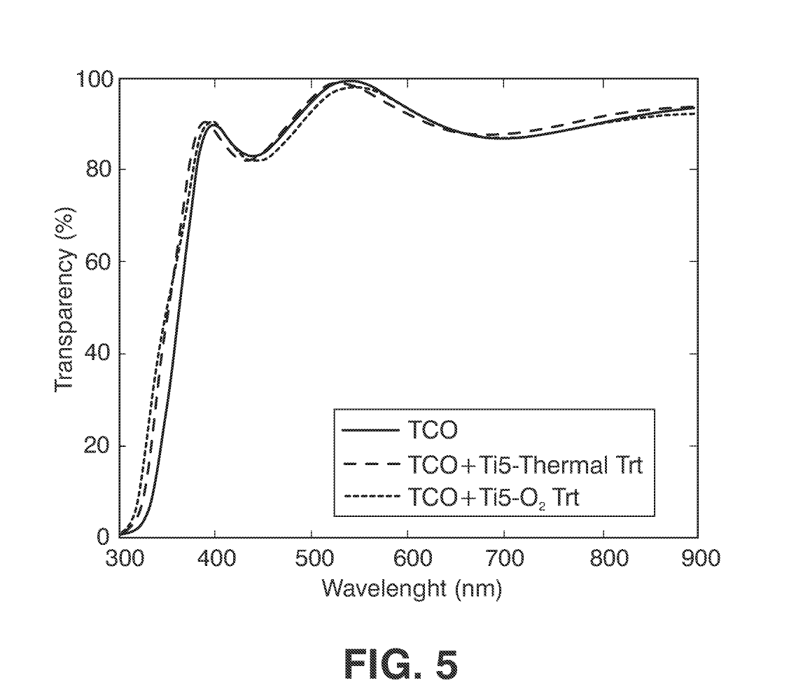

FIG. 5 shows the comparison of optical transparency against the wavelength for AZO and AZO+Ti5 nm either oxidized using an oxygen gun or thermally treated in ambient atmosphere.

In addition the oxide layer can present low electrical conductivity. It is important, in the case of direct contact with active materials, that its thickness is kept under specific values in order not to prevent injection and collection of charges. In particular when it is directly obtained by oxidizing the UTMF layer, the depth of oxidation has to be appropriately controlled so that the generated oxide, in the case it presents low electrical conductivity, does not prevent efficient injection and collection of charges at the interface with active materials.

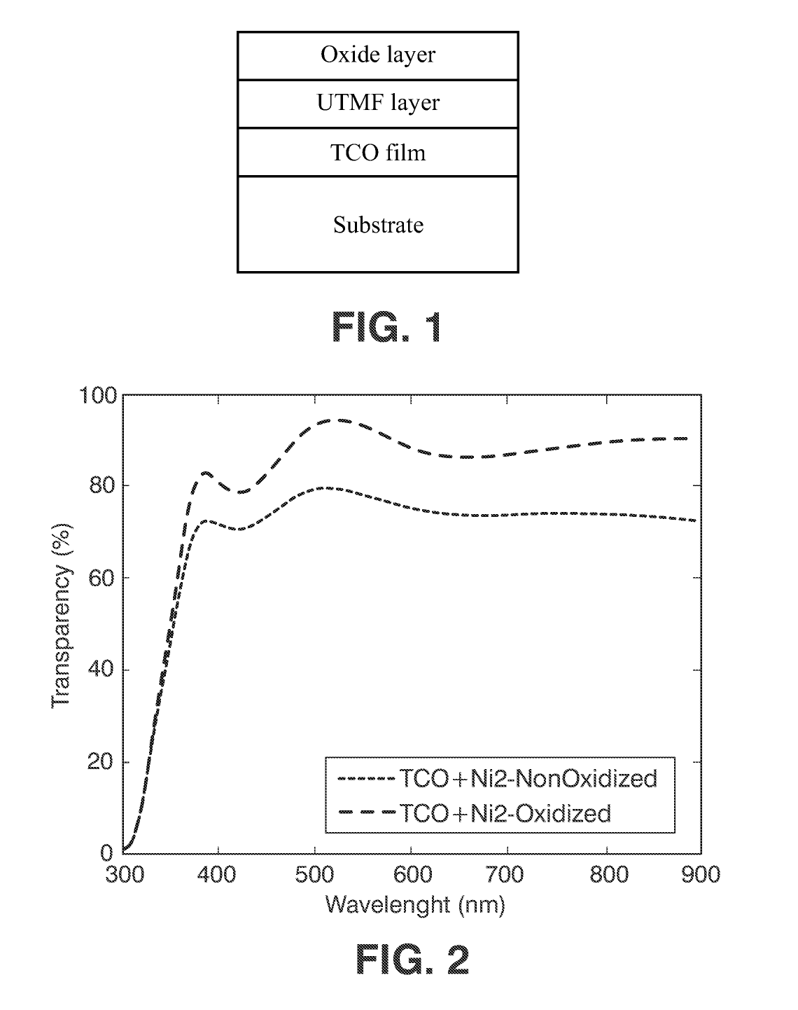

The TE structure of FIG. 1 is in its simplest form. In other embodiments the structure shown in FIG. 1 can be an element of the TE. According to a particular embodiment of the invention the electrode comprises further at least one conductive grid or mesh in contact with the TE of FIG. 1 on the oxide. Said grid or mesh comprises openings and can be prepared in several ways depending on the material and dimensions of the structure, for instance, by UV lithography, soft lithography (nano-imprinting), screen printing or by a shadow mask depending on the geometrical constraints, or by deposition which may rely on techniques similar to those used for the UTMF layer or other thicker layers, such as evaporation or electroplating. All these techniques are well known to the person skilled in the art. The UTMF can be oxidised before or after the deposition of the grid or mesh. Said grid or mesh can comprise Ni, Cr, Ti, Al, Cu, Ag, Au, doped ZnO, doped SnO₂, doped TiO₂, carbon nanotubes or Ag nanowires or a mixture thereof, being of the same or different material as the UTMF. The period and the thickness of the grid, when it consists of a periodic metallic structure, can typically range from 500 nm to 1 mm and 10 nm to 1000 nm, respectively, for the purpose of this invention. In fact the geometrical dimensions of the grid or mesh depend on the material it is made of and on the application of the electrode of the invention, as well as on current densities involved. Preferably, the fill factor of the grid or mesh when this is opaque is not more than 5%. Optionally the grid has a square, rectangular like pattern, periodic or in the form of a random mesh. In some instances the TE of this invention can be deposited on an already existing grid or mesh. According to another particular embodiment the TE of this invention can be deposited on a multilayer metallic TE structure comprising a highly conductive metal film, selected from Cu, Au, Ag, Al, and, optionally, by a UTMF, selected from Ni, Cr, Ti, Pt, Ag, Au, Al and their mixtures, which is deposited on the highly conductive metal film. More than one element of the multilayer metallic TE structure and the TE of this invention can be alternated one after the other several times to form a multilayer TE. The grid or mesh structure and the multilayer metallic TE structure can be combined at the same time with the TE of this invention. Also the up-side-down geometry, i.e. substrate, metal oxide on the substrate, UTMF on metal oxide and TCO on UTMF, might be more appropriate in some cases. For example when the substrate is an active material and the TE needs to be deposited on top of it. In this case the oxide is either deposited from an oxide target or formed through complete oxidation of a UTMF deposited before an additional UTMF layer. It is also possible to cover the up-side-down geometry with UTMF and oxide layer, i.e. the TCO is effectively in between two UTMFs layers in between two oxide layers.

The oxygen plasma and thermal treatment can be combined to obtain improved results.

The oxygen plasma might be preferable for when the substrate, TCO or any other layer forming the device and deposited before the oxidation would be affected by the high temperatures.

In some cases it might be preferable to deposit the metal oxide directly from a target. This is the case when an oxide of a metal different from the UTMF or an oxide with different properties from the oxide obtained through direct oxidation of the UTMF is preferable.

### Fabrication

The substrate used is a double side polished UV fused silica which is cleaned 10 minutes in acetone and ethanol in ultrasonic bath prior to the deposition. The cleaned substrate is then loaded in the Ajaint Orion 3 sputtering machine chamber. The substrate is then heated up to 200° C. and is continuously rotated for the uniformity of AZO deposition. Prior to the deposition, when it is in the sputtering chamber, the substrate is cleaned with oxygen plasma (oxygen base pressure of 1.06 Pa (8 mTorr) and 40 W RF power for 15 minutes. The oxygen plasma treatment activates the substrate surface and thus promotes better adhesion between the substrate and the AZO film. The sputtering is performed in a pure argon atmosphere of 0.2 Pa (1.5 mTorr) and 150 W RF power. The sputtering target used is Al doped Zinc Oxide with 3% atomic concentration of Al. The time of deposition for the film is 90 minutes which gives AZO layer of thickness ˜220 nm. Titanium of 5 nm is room-temperature deposited using RF magnetron sputtering using a target of purity level 99.99% with 75 Watt RF power and 0.13 Pa (1 mTorr) Ar pressure.

The oxygen plasma treatment of the sample involves exposing it to an oxygen plasma atmosphere, that can be obtained in the sputtering chamber filled with oxygen at a base pressure of 1.06 Pa (8 mTorr) and at 40 W RF power, for 15 minutes.

In this text, the term “comprises” and its derivations (such as “comprising”, etc.) should not be understood in an excluding sense, that is, these terms should not be interpreted as excluding the possibility that what is described and defined may include further elements, steps, etc.

On the other hand, the invention is obviously not limited to the specific embodiment(s) described herein, but also encompasses any variations that may be considered by any person skilled in the art within the general scope of the invention as defined in the claims.

1. A transparent electrode, in particular for optoelectronic applications, comprising
a substrate;
a transparent conductive oxide; and
an ultra thin metal layer of a thickness below 10 nm on the transparent conductive oxide,
wherein the electrode further comprises an oxide layer on the ultra thin metal layer, and
wherein the oxide layer is an oxide of the ultra thin metal film material, Sn or Si.

2. A transparent electrode according to claim 1, wherein the oxide layer is in contact with the substrate.

3. A transparent electrode according to claim 1, wherein the transparent conductive oxide is in contact with the substrate.

4. A transparent electrode according to claim 1, wherein the transparent conductive film is selected from indium tin oxide, Al or Ga doped zinc oxide, Ta or Nb doped titanium oxide, F doped tin oxide, and their mixtures.

5. A transparent electrode according to claim 1, wherein the ultra thin metal film is selected from a group consisting of Cu, Ni, Cr, Ti, Pt, Ag, Au, Al and their mixtures

6-7. (canceled)

8. A transparent electrode according to claim 1, further comprising a conductive mesh with openings on the transparent conductive oxide or the oxide layer.

9. A transparent electrode according to claim 8, wherein the mesh comprises Ni, Cr, Ti, Al, Cu, Ag, Au, doped ZnO, doped SnO₂, doped TiO₂, carbon nanotubes or Ag nanowires or a mixture thereof,

10. A method of manufacturing a transparent electrode, in particular for optoelectronic applications, the method comprising the steps of:
a. covering a transparent conductive oxide with an ultra thin metal layer of a thickness below 10 nm,
b. providing an oxide layer on top of the ultra thin metal layer, and
c. placing the layered structure formed in a and b on a substrate, wherein the oxide layer is an oxide of the ultra thin metal film material, Sn or Si.

11. A method according to claim 10, wherein the step b is performed by directly oxidizing the ultra thin metal layer.

12. A method according to claim 10, wherein step b is performed by depositing the oxide layer by sputtering.

13. A method according to claim 10, wherein the layered structure is placed on the substrate such that the oxide layer is on the substrate.

14. A method according to claim 10, wherein the layered structure is placed on the substrate such that the transparent conductive oxide is on the substrate.

15. A method according to claim 10, further comprising a step of providing a conductive mesh with openings on top of the layered structure.
